(19) United States
(12) Patent Application Publication
(10) Pub. No.: US 2007/0240752 A1
(43) Pub. Date: Oct. 18, 2007

(54) Built-in universal solar collector with its applied structures

(76) Inventor: Tai-Her Yang, Si-Hu Town (TW)

Correspondence Address: BACON & THOMAS, 4th Floor, 625 Slaters Lane, Alexandria, VA, 22314-1176, US

(21) Appl. No.: 11/404,862

(22) Filed: Apr. 17, 2006

(51) Int. Cl. H01L 35/00; H02N 6/00; F24J 2/00; F03G 6/00

(52) U.S. Cl. 136/206; 136/246; 60/641.8; 126/569

(57) ABSTRACT

A diversified regeneration energy supplier with built-in universal solar collector of the present invention relates to a solar collector in a spherical, polygonal, approximately cylindrical, or oval closed housing adapted with associate mask pervious to light; concave condensing structure, solar load, auxiliary facilities and optional energy collecting system of another type that share the same structure of application.

### BACKGROUND OF THE INVENTION

(a) Field of the Invention

The present invention is related to a built-in universal solar collector with its applied structures, and more particularly, to a diversified regeneration energy supplier.

(b) Description of the Prior Art

The conventional open universal solar collector for featuring solar collection by following the direction of the light source, simple structure and low production cost is usually applied in a portable solar heater, or fixed to the ground in a form of a solar tower. However, the conventional solar collector is open designed and found with poor weathering resistance; while the solar collector in closed design fails to provide universal solar collection function since its solar absorber is usually exposed at a fixed location.

### SUMMARY OF THE INVENTION

The conventional universal solar collector is usually comprised of exposed bank of reflectors that occupy large area, prevent easy installation, cleanliness and maintenance. A diversified regeneration energy supplier with built-in universal solar collector of the present invention relates to a solar collector in a spherical, polygonal, approximately cylindrical, or oval closed housing adapted with associate mask pervious to light; concave condensing structure, solar load, auxiliary facilities and optional energy collecting system of another type that share the same structure of application.

### BRIEF DESCRIPTION OF THE DRAWINGS

FIG. 1 is a perspective view of a basic structure of the present invention.

FIG. 2 is a side view of the present invention.

FIG. 3 is a perspective view of a barrel frame of the body of the present invention.

FIG. 4 is a side view of the barrel frame of the present invention.

FIG. 5 is a schematic view showing a suspension unit adapted to the present invention.

FIG. 6 is a schematic view showing a pedestal supplied with casters adapted to the present invention.

FIG. 7 is a schematic view showing that the present invention is erected with a stand.

FIG. 8 is a schematic view showing that the present invention is provided at random with a support.

FIG. 9 is a schematic view showing a surface suspension provided with anchor adapted to the prevent invention.

FIG. 10 is a schematic view showing a preferred embodiment of the present invention, which includes a solar load comprised of solar generation load and solar heat load sharing the same structure.

FIG. 11 is a schematic view of another preferred embodiment of the present invention, which includes a solar generation load and a fluidity generation unit sharing the same structure.

FIG. 12 is a schematic view of another preferred embodiment yet of the present invention, which includes a solar heat load and fluidity generation unit sharing the same structure.

FIG. 13 is a schematic view of another preferred embodiment yet of the present invention, which includes a fluidity generation unit, solar generation load and a solar heat load.

FIG. 14 is a schematic view showing that the present invention has the solar generation unit or a fluidity generation unit as the power supply.

FIG. 15 is a schematic view showing a circuit diagram of the present invention illustrated in FIG. 14.

### DETAILED DESCRIPTION OF THE PREFERRED EMBODIMENTS

A diversified regeneration energy supplier with built-in universal solar collector of the present invention relates to a solar collector in a spherical, polygonal, approximately cylindrical, or oval closed housing adapted with associate mask pervious to light; concave condensing structure, solar load, auxiliary facilities and optional energy collecting system of another type that share the same structure of application.

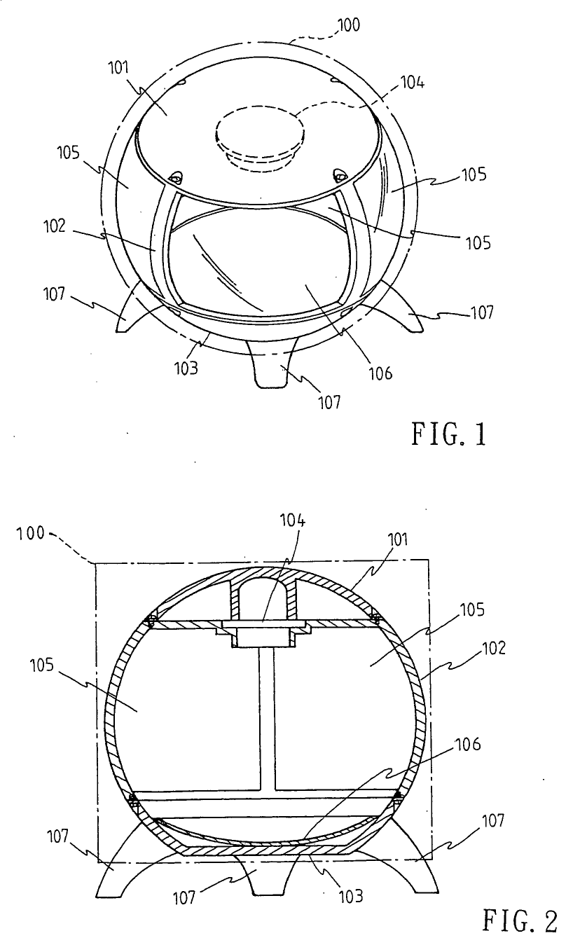

Referring to FIG. 1 for 3D schematic diagram showing a basic structure and FIG. 2 for a side view of FIG. 1 of the present invention, a diversified regeneration energy supplier with built-in universal solar collector is essentially comprised of:

A housing 100: relates to a spherical, polygonal, or approximately cylindrical casing comprised of an upper housing 101, a mid housing 102, and a lower housing 103; or a spherical upper housing or lower housing, and a mid housing in the shape of a circular frame; all three parts of the housing may be separated from one another, or two or more than two parts of the housing share the same structure;

A suspension structure may be provided externally to the upper end of the upper housing 101; a mask 105 pervious to light covers up the mid housing 102 made in a shape of a frame; the lower housing 103 contains a concave condensing unit 106; and a locking structure is disposed at the bottom of the housing as applicable. Each part of the housing may be provided with multiple sections combined to one another or the entire housing or any part of it may be made in an integrated piece;

The housing 100 for the built-in universal solar collector may be made in a fully closed structure in a circular frame or in a weathering and splash proof structure provided with multiple vents.

The upper housing 101 of the housing 100 is enclosed to contain one or a plurality of solar load 104 or any other type of power generation units if necessary, e.g., fluidity driven generation unit including one driven by a turbine activated by external wind velocity or internally rising hot air current, or a turbine providing generation and ventilation functions as driven by both of the external wind velocity and the internally rising hot air current.

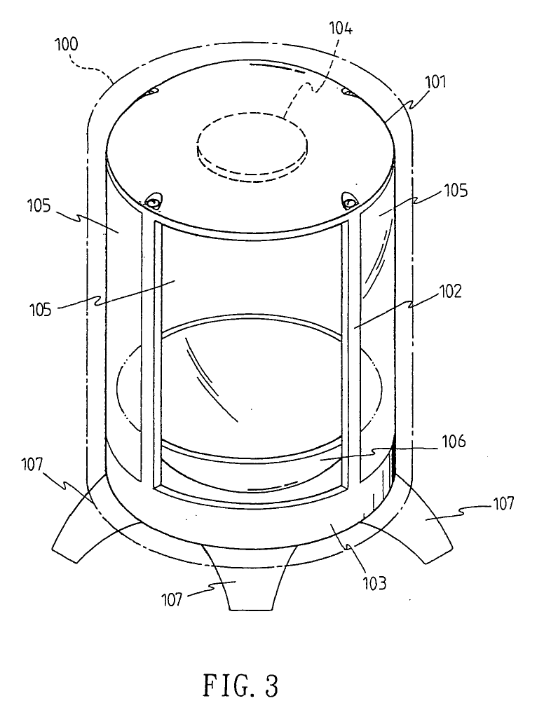

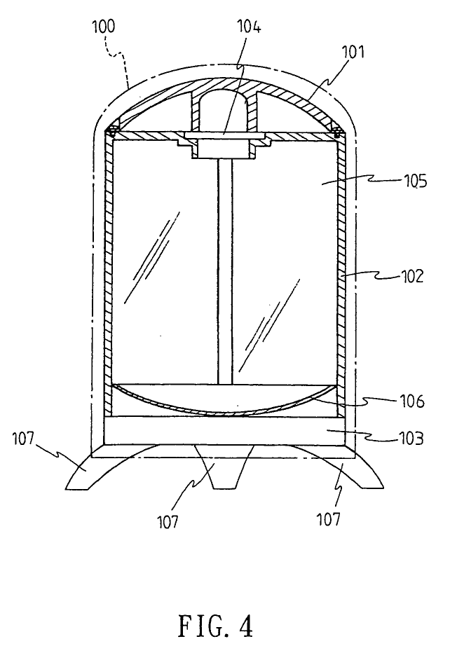

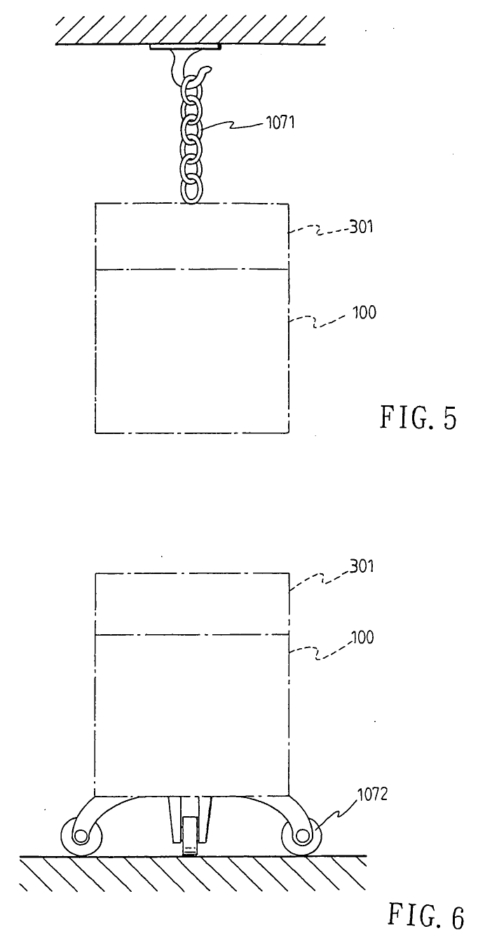

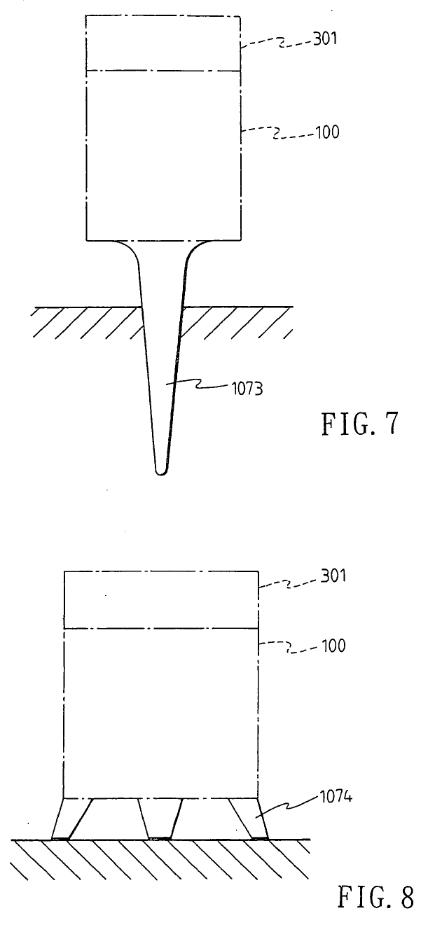

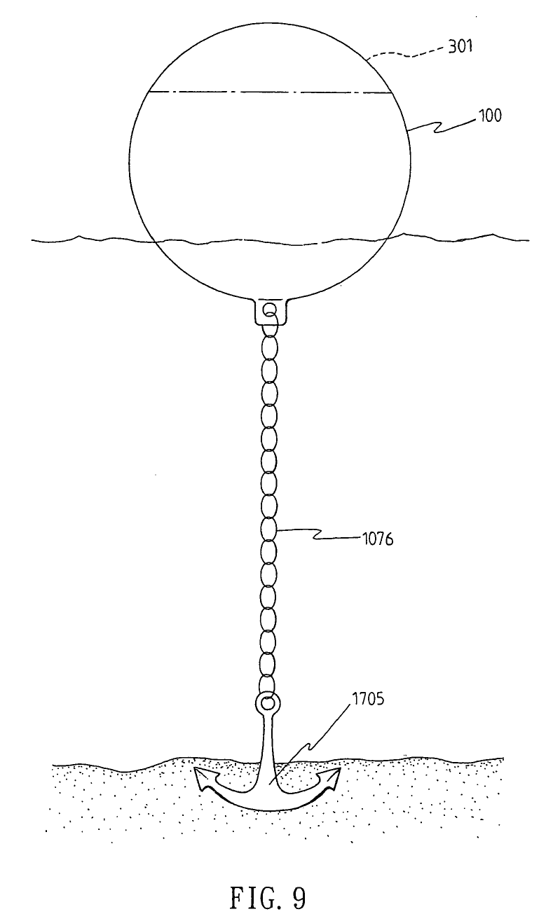

Without affecting its functional mechanism, the housing for the built-in universal solar collector may be provided in any type of structure as applicable. As illustrated in FIGS. 3 and 4, the present invention is provided in a cylindrical frame structure.
a mask pervious to light 105: related to a frame of the mid housing 102 to introduce light into a concave condensing unit 106 to be described below and to serve as a separation of enclosure; the mask pervious to light 105 is an optional item to be provided or not provided as applicable; and may be provided in stationary form or allowing open/close;
a concave condensing unit 106: comprised of an integrated or combined circular structure of concave reflection surface or a semi-spherical structure provided inside the lower housing 103 to receive photo energy passing through the mask 105 and reflect the photo energy to be collected by a solar load 104 in the upper housing 101;
a solar load 104: provided in the upper housing 101 and includes a solar generation load 1041 comprised of a solar cell that converts the photo energy into electric energy, or a fuel cell generation system that converts photo energy into electric energy, or a solar heat load 1042 that converts photo energy into thermal energy to be applied by a dryer, cooking utensils, gas heater, or any other applications that consume heat; the solar load 104 is comprised of either or both of the load 1041 or the load 1042, and is provided within the reflection area where the external light projected through the mask into the concave condensing unit 106 is reflected and condensed so to receive the photo energy reflected and condensed by the concave condensing unit 106 to be converted into electric or thermal energy; and
a locking structure 107: comprised of a sling chain or any other suspension unit 1071 as illustrated in FIG. 5, a pedestal 1072 provided with casters on the ground as illustrated in FIG. 6, a stand 1074 as illustrated in FIG. 7 comprised of multiple pedestals 1073 as illustrate din FIG. 8; a surface suspension unit comprised of an anchor cable 1076 and an anchor 1075 as illustrated in FIG. 9, or any location structure of the prior art to secure the housing 100.

FIG. 5 is a schematic view showing a suspension unit adapted to the present invention.

FIG. 6 is a schematic view showing a pedestal supplied with casters adapted to the present invention.

FIG. 7 is a schematic view showing that the present invention is erected with a stand.

FIG. 8 is a schematic view showing that the present invention is provided at random with a support.

FIG. 9 is a schematic view showing a surface suspension provided with anchor adapted to the prevent invention.

The locking structure 107 may be provided to the upper housing 101, the mid housing 102, or the lower housing 103 of the housing 100 as applicable; and in terms of the relative location and angle between the locking structure 107 and the housing 100 may be fixed or adjustable, or provided with casters to facilitate movement; and a braking device may be provided to the casters as required.

As required, combination of optional support and application for the built-in solar collector and application installations of the present invention may be provided as follows:
(1) A fixed supporting pedestal is adapted to the housing 100 to secure the housing to a stationary building;
(2) A fixed supporting pedestal is adapted to the housing 100 to secure the housing to a mobile structure;
(3) A fixed supporting pedestal is adapted to the housing 100 to secure the housing to a transportation load;
(4) A support stand to be inserted into the ground or multiple pedestals on the ground are incorporated to the housing 100;
(5) A portable support is attached to the bottom of the housing 100;
(6) Multiple pedestals each attached with a caster with or without a braking system are provided to the bottom of the housing;
(7) A chassis, wheels, and/or controllable braking system are provided to the bottom of the housing 100 for mobile or stationary installation;
(8) A suspension system is provided over the housing 100; or
(9) A submarine anchor and an anchor cable to connect both of the anchor and the housing 100 are provided to keep the housing 100 floating on the water; and the housing 100 is made in a water-proof structure.

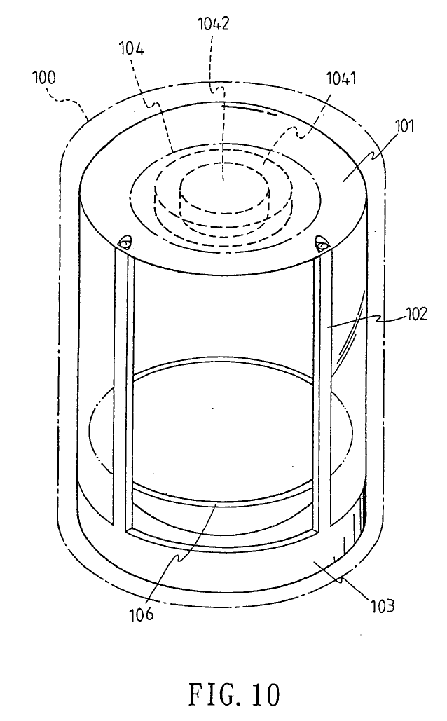

FIG. 10 is a schematic view showing a preferred embodiment of the present invention that includes a solar load comprised of solar generation load and solar heat load sharing the same structure. Wherein, the solar generation load 1041 related to a solar cell or a fuel cell generation system receives photo energy reflected and condensed by the concave condensing unit 106 and converts the photo energy into electric energy. The solar heat load 1042 receives thermal energy from the surface of the housing 100 or the radiation reflected and condensed by the concave condensing unit 106 and converts the same into thermal energy. Both of the loads 1041 and 1042 are installed on the same structure to be provided to the upper housing 101 of the housing 100.

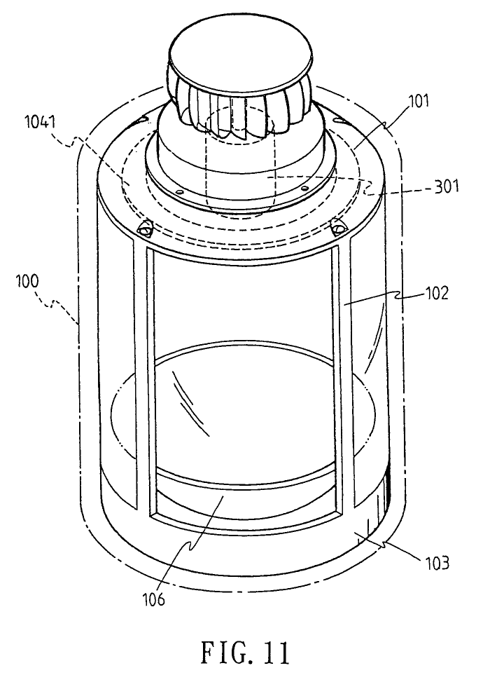

FIG. 11 is a schematic view of another preferred embodiment of the present invention that includes a solar generation load and a fluidity generation unit sharing the same structure. Wherein, the solar generation load 1041 receives and converts photo energy reflected and condensed by the concave condensing unit 106 into electric energy while the fluidity generation unit 301 is comprised of a turbine driven by external wind velocity or internally rising hot air current, or a turbine providing generation and ventilation functions as driven by both of the external wind velocity and the internally rising hot air current.

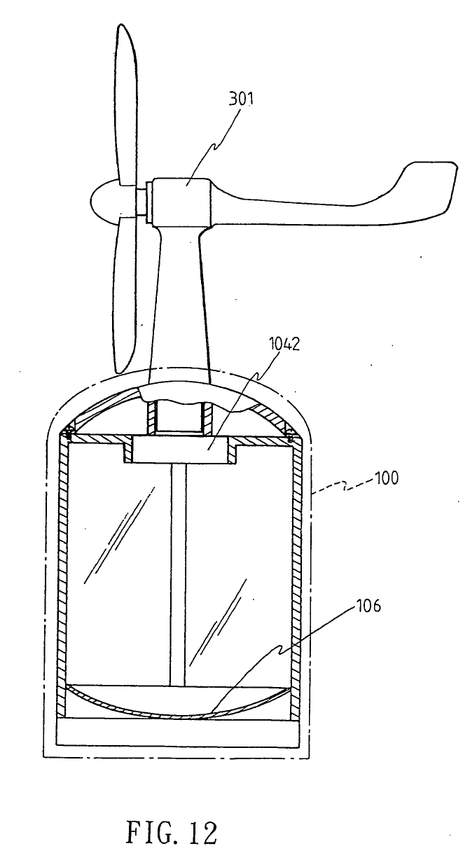

FIG. 12 is a schematic view of another preferred embodiment yet of the present invention that includes solar heat load and fluidity generation unit sharing the same structure. Wherein, the solar heat load 1042 receives and converts photo energy reflected and condensed by the concave condensing unit 106 into thermal energy to be applied by dryer, cooking utensils, gas heater, or any other applications that consume the heat while the fluidity generation unit 301 includes one driven by external wind velocity, or one driven by a turbine activated by internally rising hot air current; or a turbine providing power generation and ventilation functions as driven by both of external wind velocity and internally rising hot air current.

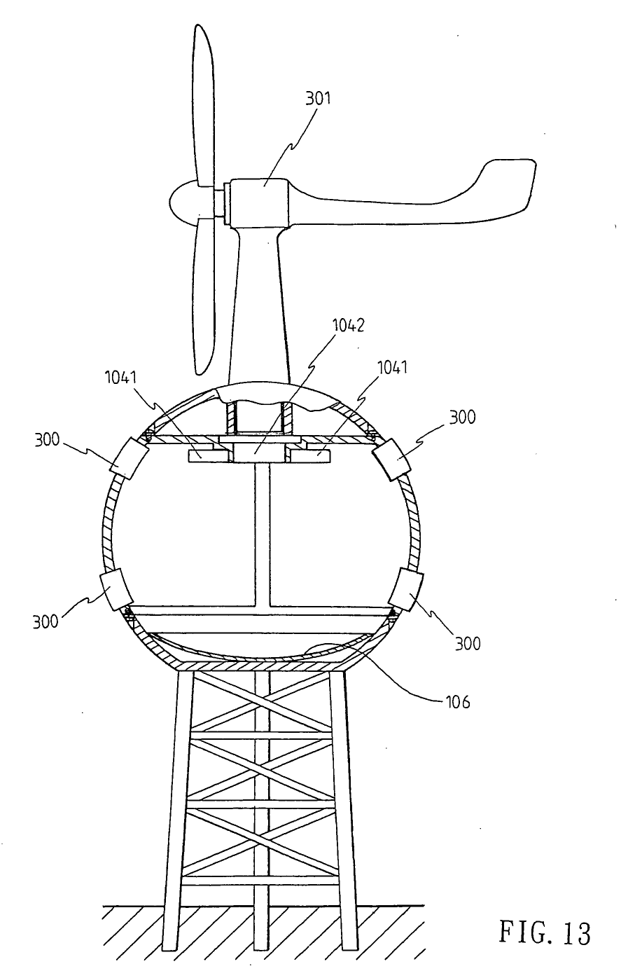

FIG. 13 is a schematic view of another preferred embodiment yet includes a fluidity generation unit, solar generation load and a solar heat load. Wherein, the solar generation load 1041 and the solar heat load 1042 receive photo energy reflected and condensed by the concave condensing unit 106 into thermal energy to be applied by dryer, cooking utensils, gas heater, or any other applications that consume the heat while the fluidity generation unit 301 includes one driven by external wind velocity, or one driven by a turbine activated by internally rising hot air current; or a turbine providing power generation and ventilation functions as driven by both of external wind velocity and internal rising hot air current.

The solar generation load 1041 provided in the built-in universal solar collector and its applied structures may function as a power supply or as a sensor.

When the present invention is provided with a solar cell that converts photo energy into electric energy to serve as the solar generation load 1041, or is provided with other type of power generation system, the back of the solar cell will emit heat to affect the operation efficiency. Furthermore, a storage device 202 shall be located at where is away from higher temperature environment. When a fuel cell generation system is provided as the solar generation load 1041, massive heat will be emitted. Therefore, an optional heat recycling system may be provided as illustrated in FIG. 13 to reclaim thermal energy, or an optional cooling device 300 may be provided in any occasion of the applications.

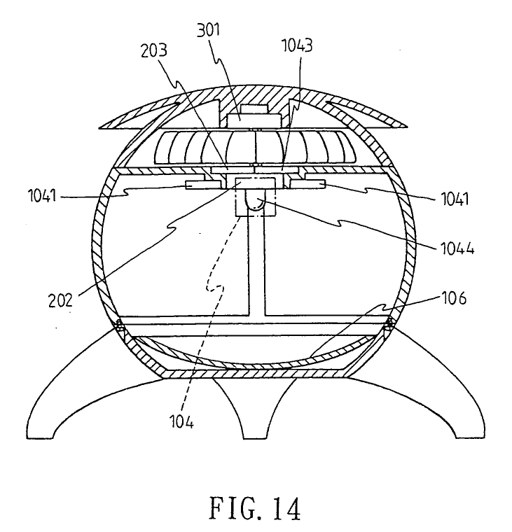

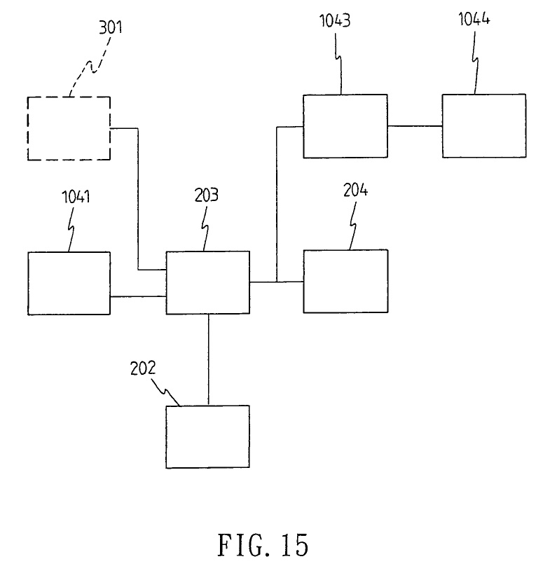

FIG. 14 is a schematic view showing that the present invention has the solar generation unit or a fluidity generation unit as the power supply. FIG. 15 is a schematic view showing a circuit diagram of the present invention illustrated in FIG. 14. Wherein, the present invention is comprised of:
the solar generation load 1041: comprised of a photo cell or a solar cell that converts photo energy into electric energy;
a fluidity generation unit 301: including one that is driven by external wind velocity or driven by a turbine activated by internally rising hot air current; or driven at the same time by external wind velocity, and a turbine activated by internally rising hot air current; either or both of the solar generation load 1041 and the fluidity generation unit 301 may be provided as applicable;
a storage device 202: an optional item related to rechargeable secondary battery or ultra capacitor to recharge the solar generation load 1041 or the fluidity generation unit 301, and a power supply to a power load 204;
A recharging control device 203: an optional item comprised of dynamo-electric or solid-state electronic device to control commencing or stopping the operation of recharging to the storage device 202 by the solar generation load 1041 or the fluidity generation unit 301, and the size or the timing of the output; and
a power load 204: related to an audio, communication or lighting device 1044 and its associate automatic, RC, or manual load control device 1043 for night hours operation, or related to a power load comprised of any other power driven load and its control device driven by the power supplied from the storage device 202 or that directly supplied by the solar generation load 1041 or the fluidity generation unit 301; the power load 204 is an optional item to be supply as a standing-along unit or sharing the same structure with the housing 100.

A cooling device 300 adapted to the built-in universal solar collector is comprised of one or a plurality of the following devices to be adapted to the housing 100 as applicable:
(1) Air passage for heat dissipation by convection is reserved on the housing 100 for the cooling device to pump air;
(2) A standing alone fan, temperature sensor, and a control means are provided for the housing 100 to control power supply from the storage device to drive the fan according to preset temperature;
(3) A turbine actuated by the hot air driven by the escaping internal heat is adapted to the housing 100;
(4) A turbine of a wind velocity generation unit is adapted to the housing 100 while the turbine also functions a ventilator; and/or
(5) In the absence of a cooling device, a passage for heat dissipation by convention is forthwith reserved on the housing 100 to function as the air passage for heat dissipation.

The cooling device 300 related to an optional item particularly in an enclosed, humidity-proof, waterproof, or pest-proof occasion.

As applicable, the following items may be provided to the upper housing 101 of the housing 100 of the built-in universal solar collector and its applied system: (1) the solar generation load 1041 to accept photo energy; (2) the solar heat load 1042; or (3) both of the solar generation load 1041 and the solar heat load 1042; or (4) the solar generation load 1041, the recharging control device 203; the storage device 202; and the lighting device 1044 and its associate automatic, RC, or manual load control device 1043 for night hours operation.

The built-in universal solar collector and its applied structures may further share the same structure with the regeneration energy source power generation unit at the housing 100. Wherein, the regeneration energy source power generation unit includes the fluidity generation unit 301 driven by hot air current, wind velocity, and water current; and/or a tidal driven generation unit 302 in the housing 100 while the storage device 202 is provided for storage of power of supplying power to the load.
(5) Plug and socket to directly supply DC power from the storage device 202 to an external device are provided;
(6) A DC-DC converter is provided to convert the DC power from the storage device 202 into DC voltage to be outputted to an external device;
(7) DC-AC inverter is provided to convert the DC power from the storage device 202 into a selected AC voltage to be outputted to an external device;

A built-in universal solar collector and its applied structures of the present invention by providing a solar collector not requiring automatic homing device to substantially reflect and condense solar light by a concave condensing device according to the change of the angle of incidence of the sunlight resulted from changes during the day and by season to a photo load to allow mobile application is innovative and providing precise functions; therefore this application for a patent is duly field.

1. A built-in universal solar collector with its applied structures is essentially comprised of:
a housing 100: relates to a spherical, polygonal, or approximately cylindrical casing comprised of an upper housing 101, a mid housing 102, and a lower housing 103; or a spherical upper housing or lower housing, and a mid housing in the shape of a circular frame; all three parts of the housing may be separated from one another, or two or more than two parts of the housing share the same structure;
a suspension structure may be provided externally to the upper end of the upper housing 101; a mask 105 pervious to light covers up the mid housing 102 made in a shape of a frame; the lower housing 103 contains a concave condensing unit 106; and a locking structure is disposed at the bottom of the housing as applicable; each part of the housing may be provided with multiple sections combined to one another or the entire housing or any part of it may be made in an integrated piece;
the housing 100 for the built-in universal solar collector may be made in a fully closed structure in a circular frame or in a weathering and splash proof structure provided with multiple vents; the upper housing 101 of the housing 100 is enclosed to contain one or a plurality of solar load 104 or any other type of power generation units if necessary, e.g., fluidity driven generation unit including one driven by a turbine activated by external wind velocity or internally rising hot air current, or a turbine providing generation and ventilation functions as driven by both of the external wind velocity and the internally rising hot air current; and without affecting its functional mechanism, the housing for the built-in universal solar collector may be provided in any type of structure as applicable;
a mask pervious to light 105: related to a frame of the mid housing 102 to introduce light into a concave condensing unit 106 to be described below and to serve as a separation of enclosure; the mask pervious to light 105 is an optional item to be provided or not provided as applicable; and may be provided in stationary form or allowing open/close;
a concave condensing unit 106: comprised of an integrated or combined circular structure of concave reflection surface or a semi-spherical structure provided inside the lower housing 103 to receive photo energy passing through the mask 105 and reflect the photo energy to be collected by a solar load 104 in the upper housing 101;
a solar load 104: provided in the upper housing 101 and includes a solar generation load 1041 comprised of a solar cell that converts the photo energy into electric energy, or a fuel cell generation system that converts photo energy into electric energy, or a solar heat load 1042 that converts photo energy into thermal energy to be applied by a dryer, cooking utensils, gas heater, or any other applications that consume heat; the solar load 104 is comprised of either or both of the load 1041 or the load 1042, and is provided within the reflection area where the external light projected through the mask into the concave condensing unit 106 is reflected and condensed so to receive the photo energy reflected and condensed by the concave condensing unit 106 to be converted into electric or thermal energy; and
a locking structure 107: comprised of a sling chain or any other suspension unit 1071, a pedestal 1072 provided with casters on the ground, a stand 1074 comprised of multiple pedestals 1073; a surface suspension unit comprised of an anchor cable 1076 and an anchor 1075, or any location structure of the prior art to secure the housing 100; the locking structure 107 may be provided to the upper housing 101, the mid housing 102, or the lower housing 103 of the housing 100 as applicable; and in terms of the relative location and angle between the locking structure 107 and the housing 100 may be fixed or adjustable, or provided with casters to facilitate movement; and a braking device may be provided to the casters as required.

2. A built-in universal solar collector with its applied structures of claim 1, wherein a fixed supporting pedestal is adapted to the housing 100 to secure the housing to a stationary building.

3. A built-in universal solar collector with its applied structures of claim 1, wherein a fixed supporting pedestal is adapted to the housing 100 to secure the housing to a mobile structure.

4. A built-in universal solar collector with its applied structures of claim 1, wherein a fixed supporting pedestal is adapted to the housing 100 to secure the housing to a transportation load.

5. A built-in universal solar collector with its applied structures of claim 1, wherein a support stand to be inserted into the ground or multiple pedestals on the ground are incorporated to the housing 100.

6. A built-in universal solar collector with its applied structures of claim 1, wherein a portable support is attached to the bottom of the housing 100.

7. A built-in universal solar collector with its applied structures of claim 1, wherein multiple pedestals each attached with a caster with or without a braking system are provided to the bottom of the housing 100.

8. A built-in universal solar collector with its applied structures of claim 1, wherein a chassis, wheels, and/or controllable braking system are provided to the bottom of the housing 100 for mobile or stationary installation.

9. A built-in universal solar collector with its applied structures of claim 1, wherein a suspension system is provided over the housing 100.

10. A built-in universal solar collector with its applied structures of claim 1, wherein a submarine anchor and an anchor cable to connect both of the anchor and the housing 100 are provided to keep the housing 100 floating on the water; and the housing 100 is made in a water-proof structure.

11. A built-in universal solar collector with its applied structures of claim 1, wherein a solar load comprised of solar generation load and solar heat load sharing the same structure; the solar generation load 1041 related to a solar cell or a fuel cell generation system receives photo energy reflected and condensed by the concave condensing unit 106 and converts the photo energy into electric energy; the solar heat load 1042 receives thermal energy from the surface of the housing 100 or the radiation reflected and condensed by the concave condensing unit 106 and converts the same into thermal energy; and both of the loads 1041 and 1042 are installed on the same structure to be provided to the upper housing 101 of the housing 100.

12. A built-in universal solar collector with its applied structures of claim 1, wherein includes a solar generation load and a fluidity generation unit sharing the same structure; the solar generation load 1041 receives and converts photo energy reflected and condensed by the concave condensing unit 106 into electric energy while the fluidity generation unit 301 is comprised of a turbine driven by external wind velocity or internally rising hot air current, or a turbine providing generation and ventilation functions as driven by both of the external wind velocity and the internally rising hot air current.

13. A built-in universal solar collector with its applied structures of claim 1, wherein the solar heat load and the fluidity generation unit sharing the same structure; the solar heat load 1042 receives and converts photo energy reflected and condensed by the concave condensing unit 106 into thermal energy to be applied by dryer, cooking utensils, gas heater, or any other applications that consume the heat while the fluidity generation unit 301 includes one driven by external wind velocity, or one driven by a turbine activated by internally rising hot air current; or a turbine providing power generation and ventilation functions as driven by both of external wind velocity and internally rising hot air current.

14. A built-in universal solar collector with its applied structures of claim 1, wherein a fluidity generation unit, solar generation load and a solar heat load are included; the solar generation load 1041 and the solar heat load 1042 receive photo energy reflected and condensed by the concave condensing unit 106 into thermal energy to be applied by dryer, cooking utensils, gas heater, or any other applications that consume the heat while the fluidity generation unit 301 includes one driven by external wind velocity, or one driven by a turbine activated by internally rising hot air current; or a turbine providing power generation and ventilation functions as driven by both of external wind velocity and internal rising hot air current.

15. A built-in universal solar collector with its applied structures of claim 1, wherein the solar generation load 1041 provided in the built-in universal solar collector and its applied structures may function as a power supply or as a sensor.

16. A built-in universal solar collector with its applied structures of claim 1, wherein a solar cell that converts photo energy into electric energy to serve as the solar generation load 1041 is provided, or other type of power generation system is provided, the back of the solar cell will emit heat to affect the operation efficiency; a storage device 202 shall be located at where is away from higher temperature environment; when a fuel cell generation system is provided as the solar generation load 1041, massive heat will be emitted; and an optional heat recycling system is provided to reclaim thermal energy, or an optional cooling device 300 may be provided in any occasion of the applications.

17. A built-in universal solar collector with its applied structures of claim 1, wherein the solar generation unit or a fluidity generation unit is provided as a power supply structure; and the present invention is comprised of:
the solar generation load 1041: comprised of a photo cell or a solar cell that converts photo energy into electric energy;
a fluidity generation unit 301: including one that is driven by external wind velocity or driven by a turbine activated by internally rising hot air current; or driven at the same time by external wind velocity, and a turbine activated by internally rising hot air current; either or both of the solar generation load 1041 and the fluidity generation unit 301 may be provided as applicable;
a storage device 202: an optional item related to rechargeable secondary battery or ultra capacitor to recharge the solar generation load 1041 or the fluidity generation unit 301, and a power supply to a power load 204;
A recharging control device 203: an optional item comprised of dynamo-electric or solid-state electronic device to control commencing or stopping the operation of recharging to the storage device 202 by the solar generation load 1041 or the fluidity generation unit 301, and the size or the timing of the output; and
a power load 204: related to an audio, communication or lighting device 1044 and its associate automatic, RC, or manual load control device 1043 for night hours operation, or related to a power load comprised of any other power driven load and its control device driven by the power supplied from the storage device 202 or that directly supplied by the solar generation load 1041 or the fluidity generation unit 301; the power load 204 is an optional item to be supply as a standing-along unit or sharing the same structure with the housing 100.

18. A built-in universal solar collector with its applied structures of claim 1, wherein a cooling device 300 adapted to the built-in universal solar collector is comprised of one or a plurality of the following devices to be adapted to the housing 100 as applicable:
(1) air passage for heat dissipation by convection is reserved on the housing 100 for the cooling device to pump air;
(2) a standing alone fan, temperature sensor, and a control means are provided for the housing 100 to control power supply from the storage device to drive the fan according to preset temperature;
(3) a turbine actuated by the hot air driven by the escaping internal heat is adapted to the housing 100;
(4) a turbine of a wind velocity generation unit is adapted to the housing 100 while the turbine also functions a ventilator;
and/or
(5) in the absence of a cooling device, a passage for heat dissipation by convention is forthwith reserved on the housing 100 to function as the air passage for heat dissipation; and the cooling device 300 related to an optional item particularly in an enclosed, humidity-proof, waterproof, or pest-proof occasion.

19. A built-in universal solar collector with its applied structures of claim 1, wherein the solar generation load 1041 to accept photo energy is provided to the upper housing 101 of the housing 100.

20. A built-in universal solar collector with its applied structures of claim 1, wherein the solar heat load 1042 is provided to the upper housing 101 of the housing 100.

21. A built-in universal solar collector with its applied structures of claim 1, wherein both of the solar generation load 1041 and the solar heat load 1042 are provided to the upper housing 101 of the housing 100.

22. A built-in universal solar collector with its applied structures of claim 1, wherein the solar generation load 1041, the recharging control device 203; the storage device 202; and the lighting device 1044 and its associate automatic, RC, or manual load control device 1043 for night hours operation are provided to the upper housing 101 of the housing 100.

23. A built-in universal solar collector with its applied structures of claim 1, wherein a regeneration energy source power generation unit is further provided at the housing 100; the regeneration energy source power generation unit includes the fluidity generation unit 301 driven by hot air current, wind velocity, and water current; and/or a tidal driven generation unit 302 in the housing 100 while the storage device 202 is provided for storage of power of supplying power to the load.

24. A built-in universal solar collector with its applied structures of claim 1, wherein plug and socket are provided to directly supply DC power from the storage device 202 to an external device are provided.

25. A built-in universal solar collector with its applied structures of claim 1, wherein a DC-DC converter is provided to convert the DC power from the storage device 202 into DC voltage to be outputted to an external device.

26. A built-in universal solar collector with its applied structures of claim 1, wherein a DC-AC inverter is provided to convert the DC power from the storage device 202 into a selected AC voltage to be outputted to an external device.
